(19) United States
(12) Patent Application Publication
(10) Pub. No.: US 2025/0072234 A1
(43) Pub. Date: Feb. 27, 2025

(54) DISPLAY APPARATUS AND METHOD OF MANUFACTURING THE SAME

(71) Applicant: Samsung Display Co., Ltd., Yongin-Si (KR)

(72) Inventors: Sukjae Park, Yongin-si (KR); Dooin Nam, Yongin-si (KR); Joongho Lee, Yongin-si (KR); Dongbum Lee, Yongin-si (KR)

(21) Appl. No.: 18/634,623

(22) Filed: Apr. 12, 2024

(30) Foreign Application Priority Data
Aug. 24, 2023 (KR) 10-2023-0111535

(51) Int. Cl. H10K 59/131; H10K 59/12; H10K 102/10

(52) U.S. Cl. CPC H10K 59/131; H10K 59/1201; H10K 2102/103

(57) ABSTRACT

A display apparatus is disclosed that includes first and second gate lines, first and second data lines, and an electrostatic blocking portion. The first and second gate line are configured to receive first and second gate voltages, respectively. The first and second data lines are configured to transfer first and second data signals to first and second pixel lines, respectively. The electrostatic blocking portion includes first and second electrostatic lines. The first electrostatic line is connected to the first data line by a first diode structure and connected to the second data line by a second diode structure. The second electrostatic line is connected to the first data line by the first diode structure and connected to the second data line by the second diode structure. The first and second electrostatic lines are electrically separated from the first and second gate line, respectively.

### CROSS-REFERENCE TO RELATED APPLICATION

This application is based on and claims priority under 35 U.S.C. § 119 to Korean Patent Application No. 10-2023-0111535, filed on Aug. 24, 2023, in the Korean Intellectual Property Office, the disclosure of which is incorporated by reference herein in its entirety.

### BACKGROUND

### 1. Field

Embodiments relate to a display apparatus and a method of manufacturing the same.

### 2. Description of the Related Art

A display apparatus receives image information and displays images. Applications of display apparatuses include miniaturized products such as mobile phones, and large-scale products such as televisions.

A display apparatus includes a plurality of pixels that receive electrical signals and emit light to display images based on those signals. Each pixel includes a light-emitting element. As an example, an organic light-emitting display apparatus includes an organic light-emitting diode (OLED) as a light-emitting element. Generally, an organic light-emitting display apparatus includes a thin-film transistor and an organic light-emitting diode disposed on a substrate, and operates when a driving current causes the organic light-emitting diode to emit light.

A display apparatus may be damaged by static electricity that takes place during a manufacturing process.

### SUMMARY

Embodiments may provide a display apparatus in which damage to a circuit caused by electrostatic discharge (ESD) may be prevented, and a method of manufacturing the display apparatus. However, such a feature is an example, and the disclosure is not limited thereto.

Additional aspects will be set forth in part in the description which follows and, in part, will be apparent from the description, or may be learned by practice of the presented embodiments of the disclosure.

An embodiment of a display apparatus includes a first gate line configured to receive a first gate voltage, a second gate line configured to receive a second gate voltage, a first data line configured to transfer a first data signal to a first pixel line, a second data line configured to transfer a second data signal to a second pixel line, and an electrostatic blocking portion including a first electrostatic line and a second electrostatic line, the first electrostatic line is connected to the first data line by a first diode structure and connected to the second data line by a second diode structure, and the second electrostatic line is connected to the first data line by the first diode structure and connected to the second data line by the second diode structure, wherein the first electrostatic line is electrically separated from the first gate line, and the second electrostatic line is electrically separated from the second gate line.

The first gate voltage may be a gate high-level voltage, and the second gate voltage may be a gate low-level voltage.

The first gate line may be connected to a 1-1 pad, the first electrostatic line may be connected to a 1-2 pad, and the 1-2 pad may be apart from the 1-1 pad.

The 1-1 pad and the 1-2 pad may be electrically separated from each other.

The second gate line may be connected to a 2-1 pad, the second electrostatic line may be connected to a 2-2 pad, and the 2-2 pad may be apart from the 2-1 pad.

The 2-1 pad and the 2-2 pad may be electrically separated from each other.

The display apparatus may further include a data driver configured to generate the first data signal and the second data signal.

The display apparatus may further include a 1-3 pad electrically connected to the data driver, and a first connection member connecting the 1-1 pad to the 1-3 pad.

The display apparatus may further include a 2-3 pad electrically connected to the data driver, and a second connection member connecting the 2-1 pad to the 2-3 pad.

The display apparatus may further include a printed circuit board including the first connection member and the second connection member, wherein the printed circuit board may be attached to the 1-1 pad, the 1-2 pad, the 1-3 pad, the 2-1 pad, the 2-2 pad, and the 2-3 pad.

The electrostatic blocking portion may be arranged between a display area in which at least one pixel is arranged, and the data driver in a plan view.

An embodiment of a method of manufacturing a display apparatus includes forming, on a substrate, a first gate line configured to receive a first gate voltage and a second gate line configured to receive a second gate voltage, forming, on the substrate, a first data line configured to transfer a first data signal to a first pixel line, and a second data line configured to transfer a second data signal to a second pixel line, forming, on the substrate, an electrostatic blocking portion including a first electrostatic line electrically connected to the first gate line, and a second electrostatic line electrically connected to the second gate line, forming, on the substrate, a data driver configured to generate the first data signal and the second data signal, electrically separating the first gate line from the first electrostatic line and electrically separating the second gate line from the second electrostatic line, and attaching a printed circuit board to the substrate, wherein the printed circuit board includes a first connection member electrically connecting the first gate line to the data driver, and a second connection member electrically connecting the second gate line to the data driver.

The first gate voltage may be a gate high-level voltage, and the second gate voltage may be a gate low-level voltage.

The method may further include forming a 1-1 pad electrically connected to the first gate line and a 2-1 pad electrically connected to the second gate line, and forming a 1-2 pad electrically connected to the first electrostatic line and forming a 2-2 pad electrically connected to the second electrostatic line.

The forming of the electrostatic blocking portion may include forming a first additional connection portion electrically connecting the 1-1 pad to the 1-2 pad, and forming a second additional connection portion electrically connecting the 2-1 pad to the 2-2 pad.

The electrically separating of the first gate line from the first electrostatic line and the electrically separating of the second gate line from the second electrostatic line may include removing or disconnecting the first additional connection portion, and removing or disconnecting the second additional connection portion.

The method may further include forming a 1-3 pad and a 2-3 pad, which are electrically connected to the data driver, wherein the first connection member may electrically connect the 1-1 pad to the 1-3 pad, and the second connection member may electrically connect the 2-1 pad to the 2-3 pad.

An embodiment of a display apparatus includes a first gate line configured to receive a first gate voltage, a second gate line configured to receive a second gate voltage, a first data line configured to transfer a first data signal to a first pixel line, a second data line configured to transfer a second data signal to a second pixel line, an electrostatic blocking portion including a first electrostatic line and a second electrostatic line, the first electrostatic line is connected to the first data line by a first diode structure and connected to the second data line by a second diode structure, and the second electrostatic line is connected to the first data line by the first diode structure and connected to the second data line by the second diode structure, a first switch configured to electrically connect the first gate line and the first electrostatic line or electrically separate the first gate line and the first electrostatic line, a second switch configured to electrically connect the second gate line and the second electrostatic line or electrically separate the second gate line and the second electrostatic line, and a switch controller configured to control the first switch and the second switch.

The first gate voltage may be a gate high-level voltage, and the second gate voltage may be a gate low-level voltage.

The display apparatus may further include a data driver configured to generate the first data signal and the second data signal, and a printed circuit board including a first connection member electrically connecting the first gate line to the data driver, and a second connection member electrically connecting the second gate line to the data driver.

The switch controller may be configured to control the first switch and the second switch, based on an electrical connection state of the first gate line, the second gate line, and the data driver.

When a first state is a state of the display apparatus before including the printed circuit board, in the first state, the switch controller may be configured to control the first switch to electrically connect the first gate line to the first electrostatic line, and configured to control the second switch to electrically connect the second gate line to the second electrostatic line.

When a second state is a state of the display apparatus after including the printed circuit board, in the second state, the switch controller may be configured to control the first switch to electrically separate the first gate line from the first electrostatic line, and configured to control the second switch to electrically separate the second gate line from the second electrostatic line.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display panel of a display apparatus according to an embodiment;

FIG. 2 is an equivalent circuit diagram of a pixel included in the display panel of FIG. 1;

FIG. 3 is a schematic cross-sectional view of a pixel of the display panel of FIG. 1;

FIGS. 4, 5, and 6 are schematic plan views of an example of a region A of FIG. 1 according to time series;

FIGS. 7, 8, and 9 are schematic plan views of an example of a region A of FIG. 1 according to time series; and

FIG. 10 is a schematic plan view of a portion of a display apparatus according to a comparative example.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.” Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another. In addition, the singular forms “a,” “an,” and “the” as used herein are intended to include the plural forms as well unless the context clearly indicates otherwise.

As used herein, when various elements such as a layer, a region, a plate, and the like are disposed “on” another element, not only the elements may be disposed “directly on” the other element, but another element may be disposed therebetween.

In addition, sizes of elements in the drawings may be exaggerated or reduced for convenience of explanation. As an example, the size and thickness of each element shown in the drawings are arbitrarily represented for convenience of description, and thus, the disclosure is not necessarily limited thereto.

It will be understood that the terms “comprise,” “comprising,” “include” and “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

In the case where a certain embodiment may be implemented differently, a specific process order may be performed in the order different from the described order. As an example, two processes successively described may be simultaneously performed substantially and performed in the opposite order.

It will be understood that when a layer, region, or element is referred to as being “connected” to another layer, region, or element, it may be “directly connected” to the other layer, region, or element or may be “indirectly connected” to the other layer, region, or element with another layer, region, or element located therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

Hereinafter, a display apparatus in which a damage to a circuit caused by electrostatic discharge (ESD) may be prevented, and a method of manufacturing the display apparatus are described in detail according to embodiments.

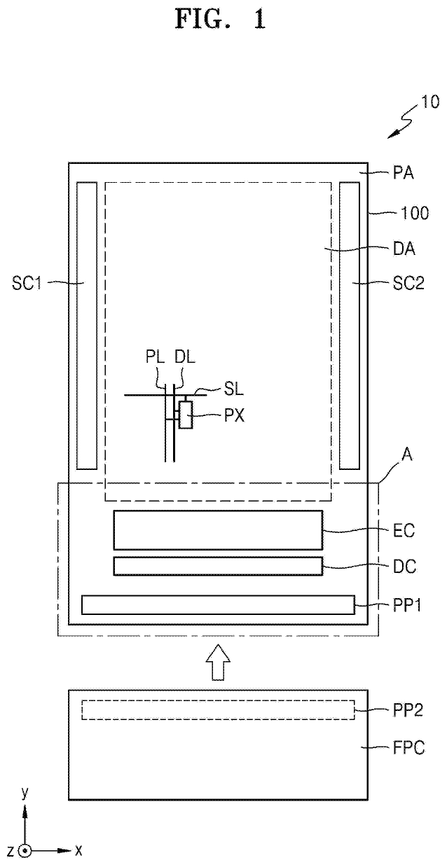

FIG. 1 is a schematic plan view of a display panel of a display apparatus according to an embodiment.

For reference, detailed description of FIG. 1 is made below with reference to other drawings, for convenience of description, and schematic description of FIG. 1 is mainly made.

As shown in FIG. 1, the display apparatus according to an embodiment includes a display panel 10. As long as a display apparatus includes the display panel 10, any display apparatus may be used. As an example, the display apparatus may include various apparatuses such as smartphones, tablet computers, laptop computers, televisions, advertisement boards, or the like. Because a display apparatus according to an embodiment includes thin-film transistors, a capacitor, and the like, the thin-film transistors, the capacitor, and the like may be implemented by conductive layers and insulating layers.

The display panel 10 includes a display area DA and a peripheral area PA outside the display area DA. It is shown in FIG. 1 that the display area DA has a rectangular shape. However, the embodiment is not limited thereto. The display area DA may have various shapes, for example, circular shapes, elliptical shapes, polygonal shapes, or shapes of specific figures.

The display area DA is a region in which images are displayed, and a plurality of pixels PX may be arranged in the display area DA. Each pixel PX may include a light-emitting element such as an organic light-emitting diode. Each pixel PX may be configured to emit, for example, red, green, or blue light. The pixel PX may be connected to a pixel circuit including a thin-film transistor, a storage capacitor, and the like. The pixel circuit may be connected to a scan line SL, a data line DL, and a driving voltage line PL, wherein the scan line SL is configured to transfer scan signals, the data line DL crosses the scan line SL and is configured to transfer data signals, and the driving voltage line PL is configured to supply a driving voltage. The scan line SL may extend in an x direction (referred to as a second direction, hereinafter), the data line DL and the driving voltage line PL may extend in a y direction (referred to as a first direction, hereinafter).

The pixel PX may be configured to emit light of a brightness corresponding to an electrical signal from the pixel circuit electrically connected thereto. The display area DA may be configured to display preset images by using light emitted from the pixel PX. For reference, the pixel PX may be defined as an emission area that is configured to emit light having one of red, green, and blue.

The peripheral area PA is a region in which pixels PX are not arranged and may be a region that is configured not to display images. A power supply line for driving the pixel PX and the like may be arranged in the peripheral area PA. In addition, pads may be arranged in the peripheral area PA, and a printed circuit board including a driving circuit, or an integrated circuit element such as a driver integrated circuit (IC) may be arranged to be electrically connected to the plurality of pads.

As an example, a data driver DC may be arranged in the peripheral area PA. The data driver DC may be mounted on the display panel 10 using a chip-on-glass (COG) method, a chip-on-film (COF) method, a chip-on-plastic (COP) method, or the like. The data driver DC may be configured to generate electrical signals in response to power and signals transferred from the outside, and provide the same to pixels PX arranged in the display area DA.

In addition, a first pad portion PP1 may be arranged in the peripheral area PA, wherein the first pad portion PP1 is electrically connected to the data driver DC through a wiring or a conductive layer. A printed circuit board FPC may be attached to the first pad portion PP1 in the peripheral area PA.

As an example, the printed circuit board FPC may be electrically connected to the data driver DC through the first pad portion PP1. For this purpose, the printed circuit board FPC may include a second pad portion PP2 corresponding to the first pad portion PP1. As an example, the printed circuit board FPC or the second pad portion PP2 may be attached to the first pad portion PP1 by an adhesive member. As an example, the adhesive member may be an anisotropic conductive film (ACF).

The printed circuit board FPC may be a flexible printed circuit board (FPCB) to which a flexible characteristic is given. The FPCB may be folded or warped. The FPCB may be folded below the backside of the display panel 10 to overlap at least a partial region of the display panel 10.

As shown in FIG. 1, scan drivers SC1 and SC2 may be arranged in the peripheral area PA of the display panel 10. Although, for convenience of description, it is shown that the scan drivers SC1 and SC2 are arranged in two opposite sides of the display area DA, this is only one example, and the positions of the scan drivers SC1 and SC2 are not limited to the two opposite sides of the display area DA. In addition, the scan drivers SC1 and SC2 may be implemented as only one scan driver depending on a driving method or an integration degree. The scope of the disclosure in the present specification is not limited to the number of scan drivers SC1 and SC2, which is obvious to those of ordinary skill in the art.

The display panel 10 may further include an electrostatic blocking portion EC. The electrostatic blocking portion EC may include electrostatic discharge (ESD) protection circuit configured to protect an internal circuit from a damage caused by a high-voltage pulse. The ESD protection circuit may prevent static charges from flowing into the internal circuit and send the static charges to the ground.

Although it is shown in FIG. 1 that the length of each of the data driver DC and the electrostatic blocking portion EC in a ±x direction is equal to the length of the display area DA the ±x direction, the embodiment is not limited thereto and the lengths may be different from each other. As an example, the length of each of the data driver DC and the electrostatic blocking portion EC in the ±x direction may be less than the length of the display area DA the ±x direction.

For reference, because the display panel 10 includes a substrate 100, it may be understood that the substrate 100 includes the display area DA and the peripheral area PA. The substrate 100 is described below in detail.

In addition, a plurality of transistors may be arranged in the display area DA. In the plurality of transistors, a first terminal of a transistor may be a source electrode or a drain electrode, and a second terminal may be an electrode different from the first terminal depending on the kind (an N type or a P type) of the transistor or an operation condition. As an example, in the case where the first terminal is a source electrode, the second terminal may be a drain electrode.

The plurality of transistors may include a driving transistor, a data-write transistor, a compensation transistor, an initialization transistor, and an emission control transistor. The driving transistor may be connected between the driving voltage line PL and an organic light-emitting diode OLED, and the data-write transistor may be connected to the data line DL and the driving transistor and configured to perform a switching operation of transferring a data signal transferred through the data line DL.

The compensation transistor may be turned on according to a scan signal transferred through the scan line SL and configured to compensate for a threshold voltage of the driving transistor by connecting the driving transistor to the organic light-emitting diode OLED.

The initialization transistor may be turned on according to a scan signal transferred through the scan line SL and configured to initialize a gate electrode of the driving transistor by transferring an initialization voltage to the gate electrode of the driving transistor. A scan line connected to the initialization transistor may be a separate scan line different from a scan line connected to the compensation transistor.

The emission control transistor may be turned on according to an emission control signal transferred through an emission control line, and as a result, a driving current may flow through the organic light-emitting diode OLED.

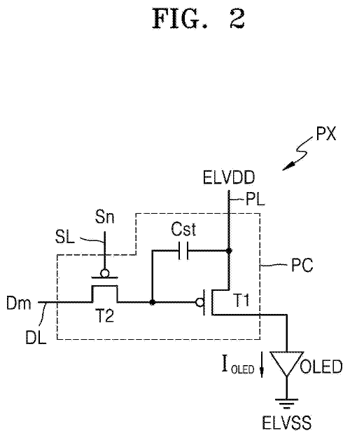

The organic light-emitting diode OLED may include an anode and a cathode, and the cathode may receive a second power voltage (see ELVSS in FIG. 2). The organic light-emitting diode OLED may be configured to display images by receiving the driving current from the driving transistor and emitting light.

Hereinafter, although an organic light-emitting display apparatus is described as an example of the display apparatus according to an embodiment, the display apparatus is not limited thereto. In another embodiment, the display apparatus according to an embodiment may be an inorganic light-emitting display apparatus or a quantum-dot light-emitting display apparatus. As an example, an emission layer of a display element of the display apparatus may include an organic material or an inorganic material. In addition, the display apparatus may include the emission layer and quantum dots arranged on the path of light emitted from the emission layer.

FIG. 2 is an equivalent circuit diagram of a pixel included in the display panel of FIG. 1.

For reference, in the description of FIG. 2, contents identical to or repeating those described with reference to FIG. 1 may be omitted.

As shown in FIG. 2, each pixel PX may include a pixel circuit PC and the organic light-emitting diode OLED connected to the pixel circuit PC, wherein the pixel circuit PC is connected to the scan line SL and the data line DL.

The pixel circuit PC includes a driving thin-film transistor T1, a switching thin-film transistor T2, and a storage capacitor Cst. The switching thin-film transistor T1 is connected to the scan line SL and the data line DL, and configured to transfer a data signal Dm to the driving thin-film transistor T1 according to a scan signal Sn, wherein the data signal Dm is input through the data line DL, and the scan signal Sn is input through the scan line SL.

The storage capacitor Cst may be connected to the switching thin-film transistor T2 and the driving voltage line PL and configured to store a voltage corresponding to a difference between a voltage transferred from the switching thin-film transistor T2 and a first power voltage ELVDD supplied to the driving voltage line PL.

The second power voltage ELVSS may be a driving voltage having a relatively low level compared to the first power voltage ELVDD. The level of the driving voltage supplied to each pixel PX may be a difference between the levels of the first power voltage ELVDD and the second power voltage EVLSS.

The driving thin-film transistor T1 may be connected to the driving voltage line PL and the storage capacitor Cst and configured to control a driving current according to the voltage stored in the storage capacitor Cst, the driving current flowing from the driving voltage line PL to the organic light-emitting diode OLED. The organic light-emitting diode OLED may be configured to emit light having a preset brightness corresponding to the driving current.

Although it is described with reference to FIG. 2 that the pixel circuit PC includes two thin-film transistors and one storage capacitor, the embodiment is not limited thereto.

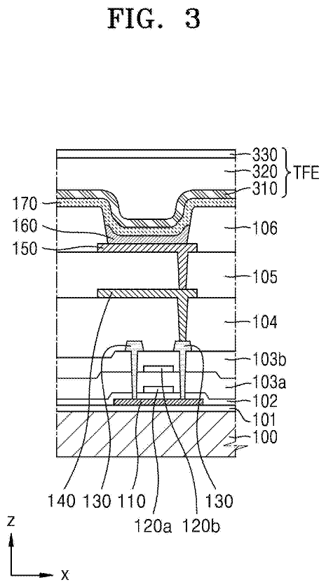

FIG. 3 is a schematic cross-sectional view of a pixel PX of the display panel of FIG. 1.

For reference, in the description of FIG. 3, contents identical to or repeating those described with reference to FIGS. 1 and 2 may be omitted.

Referring to FIGS. 1 and 3, the substrate 100 may include the display area DA and regions corresponding to the peripheral area PA outside the display area DA. The substrate 100 may include various flexible or bendable materials. As an example, the substrate 100 may include glass, metal, or a polymer resin. In addition, the substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers each including the polymer resin, and a barrier layer including an inorganic material (such as silicon oxide, silicon nitride, and silicon oxynitride) therebetween. However, various modifications may be made.

Alternatively, to implement ultra-high resolution, the substrate 100 may include a semiconductor material, such as a Group IV semiconductor, a Group III-V compound semiconductor, or a Group II-VI compound semiconductor. The substrate 100 may include a silicon layer. That is, the substrate 100 may be a semiconductor substrate including a semiconductor material. The substrate 100 may be a substrate including a silicon wafer formed by using a semiconductor process. In this case, an active layer is formed in the inner portion of the substrate 100 including the silicon wafer, and a gate line, a data line, and a transistor may be disposed on the upper surface of the substrate 100. As described above, an organic light-emitting diode OLED that uses the substrate including the silicon wafer may be referred to as an OLED on silicon (OLEDoS). As an example, in the case of an OLEDoS, a complementary metal oxide semiconductor (CMOS) process is required, and an OLED element may be formed on an electrode formed by the CMOS process. To implement each of colors R, G, and B in an OLEDoS, generally, a white OLEDs are made and color filters are placed on the white OLEDs to implement the R, G, and B colors. OLEDoS may be mainly used for extended reality (XR), and the like, and may implement ultra-high definition of 8K or more in a small area of about 1 to 2 inches. When a semiconductor substrate is used, precise control of pixels arranged at ultra-high resolution may be performed. However, the embodiment is not limited thereto.

A buffer layer 101 may be disposed on the substrate 100. The buffer layer 101 may prevent impurity ions from diffusing, prevent penetration of moisture or external air, and serve as a barrier layer for planarizing a surface or a blocking layer. The buffer layer 101 may include silicon oxide, silicon nitride, or silicon oxynitride. In addition, the buffer layer 101 may allow a semiconductor layer 110 to be uniformly crystalized by adjusting a rate of heat provision during a crystallization process for forming the semiconductor layer 110.

The semiconductor layer 110 may be disposed on the buffer layer 101. The semiconductor layer 110 may include polycrystalline silicon, and include a channel region not doped with impurities, a source region, and a drain region on two opposite sides of the channel region, each doped with impurities. Here, impurities may change depending on the kind of a thin-film transistor and may be N-type impurities or P-type impurities.

A gate insulating layer 102 may be disposed on the semiconductor layer 110. The gate insulating layer 102 may be a construction for securing insulation between the semiconductor layer 110 and a first gate layer 120a. The gate insulating layer 102 may include an inorganic material such as silicon oxide, silicon nitride, or silicon oxynitride, and may be disposed between the semiconductor layer 110 and the first gate layer 120a. In addition, the gate insulating layer 102 may have a shape corresponding to an entire surface of the substrate 100 and have a structure in which contact holes are formed in preset portions. As described above, the insulating layer including the inorganic material may be formed by chemical vapor deposition (CVD) or atomic layer deposition (ALD). This is also applicable to embodiments below and modifications thereof.

The first gate layer 120a may be disposed on the gate insulating layer 102. The first gate layer 120a may be disposed at a position overlapping the semiconductor layer 110 vertically and may include at least one metal among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), and titanium (Ti), tungsten (W), and copper (Cu).

A first interlayer insulating layer 103a may be disposed on the first gate layer 120a. The first interlayer insulating layer 103a may cover the first gate layer 120a. The first interlayer insulating layer 103a may include an inorganic material. As an example, the first interlayer insulating layer 103a may include metal oxide or metal nitride, and specifically, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). In an embodiment, the first interlayer insulating layer 103a may have a double structure of SiOₓ/SiN_{y} or SiNₓ/SiO_{y}.

A second gate layer 120b may be disposed on the first interlayer insulating layer 103a. The second gate layer 120b may be disposed at a position overlapping the first gate layer 120a vertically and may include at least one metal among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), and titanium (Ti), tungsten (W), and copper (Cu).

The first gate layer 120a and the second gate layer 120b may constitute the storage capacitor Cst described with reference to FIG. 2. The first gate layer 120a may be one electrode of the storage capacitor Cst, and the second gate layer 120b may be the other electrode of the storage capacitor Cst.

The second interlayer insulating layer 103b may be disposed on the second gate layer 120b. The second interlayer insulating layer 103b may cover the second gate layer 120b. The second interlayer insulating layer 103b may include an inorganic material. As an example, the second interlayer insulating layer 103b may include metal oxide or metal nitride, and specifically, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). In an embodiment, the second interlayer insulating layer 103b may have a double structure of SiOₓ/SiN_{y} or SiNₓ/SiO_{y}.

A first conductive layer 130 may be disposed on the second interlayer insulating layer 103b. The first conductive layer 130 may serve as first and second electrodes connected to a source and adrain region, respectively, of a semiconductor layer through holes included in the second interlayer insulating layer 103b. The first conductive layer 130 may include at least one metal among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). As an example, the first conductive layer 130 may include a Ti layer, an Al layer, or a Cu layer.

A first organic insulating layer 104 may be disposed on the first conductive layer 130. The first organic insulating layer 104 may cover the upper portion of the first conductive layer 130, have an approximately flat upper surface, and may be an organic insulating layer serving as a planarization layer. The first organic insulating layer 104 may include, for example, acryl, benzocyclobutene (BCB), or hexamethyldisiloxane (HMDSO). The first organic insulating layer 104 may include a single layer or a multi-layer. However, various modifications may be made.

A second conductive layer 140 may be disposed on the first organic insulating layer 104. The second conductive layer 140 may serve as an electrode connected to the source/drain region of the semiconductor layer through a through hole included in the first organic insulating layer 104. The second conductive layer 140 may include at least one metal among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). As an example, the second conductive layer 140 may include a Ti layer, an Al layer, or a Cu layer.

A second organic insulating layer 105 may be disposed over the first conductive layer 130. The second organic insulating layer 105 may cover the upper portion of the first conductive layer 130, have an approximately flat upper surface, and may be an organic insulating layer serving as a planarization layer. The second organic insulating layer 105 may include an organic material, such as acryl, benzocyclobutene (BCB), or hexamethyldisiloxane (HMDSO). The second organic insulating layer 105 may include a single layer or a multi-layer. However, various modifications may be made.

In addition, although not shown in FIG. 3, an additional conductive layer and an additional insulating layer may be disposed between the conductive layer and a pixel electrode 150, and applicable to various embodiments. In this case, the additional conductive layer may include the same material as the conductive layer and have the same layered structure as the conductive layer. The additional insulating layer may include the same material as the organic insulating layer and have the same layered structure as the organic insulating layer.

The pixel electrode 150 may be disposed on the second organic insulating layer 105. The pixel electrode 150 may be connected to the second conductive layer 140 through a contact hole formed in the second organic insulating layer 105. A display element may be disposed on the pixel electrode 150. The organic light-emitting diode OLED may be used as the display element. That is, the organic light-emitting diode OLED may be disposed on the pixel electrode 150. The pixel electrode 150 may include a light-transmissive conductive layer and a reflective layer, wherein the light-transmissive conductive layer includes a light-transmissive conductive oxide such as indium tin oxide (ITO), indium oxide (In₂O₃), or indium zinc oxide (IZO), and the reflective layer includes metal such as aluminum (Al) or silver (Ag). As an example, the pixel electrode 150 may have a three-layered structure of ITO/Ag/ITO.

A pixel-defining layer 106 may be disposed on the second organic insulating layer 105 and arranged to cover the edges of the pixel electrode 150. That is, the pixel-defining layer 106 may cover the edges of the pixel electrode 150. The pixel-defining layer 106 has an opening corresponding to the pixel PX, and the opening may be formed to expose at least the central portion of the pixel electrode 150. The pixel-defining layer 106 may include, for example, an organic material such as polyimide or HMDSO, or may include an inorganic material such as a silicon compound (e.g., SiNₓ, SiOₓ, and the like).

In addition, a spacer (not shown) may be disposed on the pixel-defining layer 106. Although it is shown that the spacer (not shown) is arranged in the peripheral area PA, the spacer may be arranged in the display area DA. The spacer (not shown) may prevent the organic light-emitting diode OLED from being damaged by sagging of a mask in the manufacturing process that uses the mask. The spacer (not shown) may include an organic insulating material and include a single layer or a multi-layer.

An intermediate layer 160 may be disposed on the pixel electrode 150. As an example, the intermediate layer 160 may be disposed in the opening of the pixel-defining layer 106. As an example, the intermediate layer 160 and an opposite electrode layer 170 may be disposed in the opening of the pixel-defining layer 106.

The intermediate layer 160 may include a low-molecular weight or polymer material and include a hole injection layer, a hole transport layer, an emission layer, an electron transport layer, or an electron injection layer.

The opposite electrode 170 may include a light-transmissive conductive layer including a light-transmissive conductive oxide such as ITO, In₂O₃, or IZO. Alternatively, the opposite electrode 170 may be a conductive layer including silver (Ag) or magnesium (Mg). The pixel electrode 150 is used as an anode, and the opposite electrode 170 is used as a cathode. The polarities of the electrodes may be reversely applied.

The structure of the intermediate layer 160 is not limited thereto, and the intermediate layer 160 may have various structures. As an example, at least one of layers constituting the intermediate layer 160 may be integrally formed like the opposite electrode 170. Alternatively, the intermediate layer 160 may include a layer patterned to correspond to each of a plurality of pixel electrodes 150.

The opposite electrode 170 may be arranged in the upper portion of the display area DA and arranged over the entire surface of the display area DA. As an example, the opposite electrode 170 may be integrally formed to cover the plurality of pixels. The opposite electrode 170 may be in electrical contact with a common power supply line (not shown) arranged in the peripheral area PA. In an embodiment, the opposite electrode 170 may extend to a blocking wall (not shown).

A thin-film encapsulation layer TFE may be disposed on the opposite electrode 170. The thin-film encapsulation layer TFE may cover the display area DA entirely and be arranged to extend the peripheral area PA and cover at least a portion of the peripheral area PA.

The thin-film encapsulation layer TFE may include a first inorganic encapsulation layer 310, a second inorganic encapsulation layer 330, and an organic encapsulation layer 320 therebetween. The first inorganic encapsulation layer 310 and the second inorganic encapsulation layer 330 may include one or more inorganic materials such as aluminum oxide, titanium oxide, tantalum oxide, hafnium oxide, zinc oxide, silicon oxide, silicon nitride, and silicon oxynitride.

The organic encapsulation layer 320 may include a monomer-based material or a polymer-based material. The polymer-based material may include an acryl-based resin, an epoxy-based resin, polyimide, and polyethylene. In an embodiment, the organic encapsulation layer 320 may include acrylate.

The blocking wall (not shown) may be arranged in the peripheral area PA of the substrate 100. In an embodiment, although the blocking wall (not shown) may include a portion of the first organic insulating layer 104, a portion of the second organic insulating layer 105, a portion of the pixel-defining layer 106, and a portion of the spacer (not shown), the embodiment is not limited thereto.

Depending on the case, the blocking wall (not shown) may be arranged to surround the display area DA and configured to prevent the organic encapsulation layer 320 of the thin-film encapsulation layer TFE from overflowing to the outside of the substrate 100.

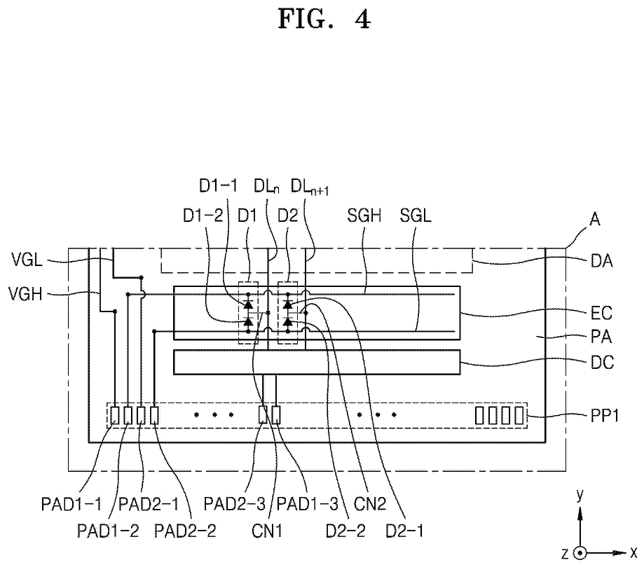

FIGS. 4 to 6 are schematic plan views of an example of a region A of FIG. 1 according to time series.

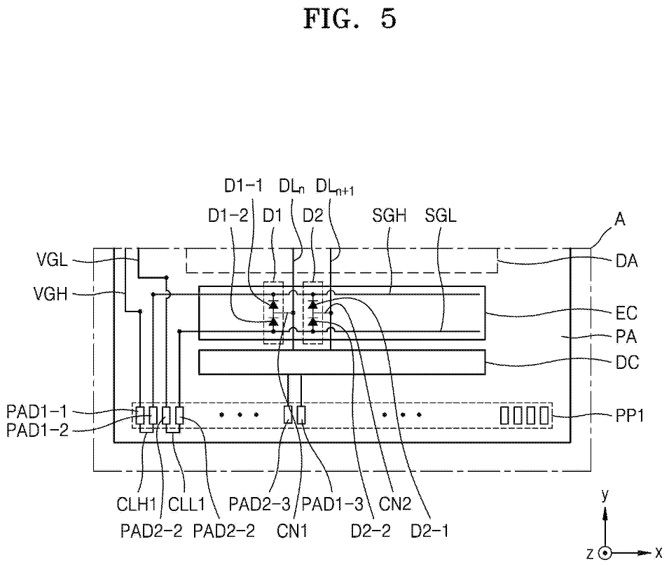

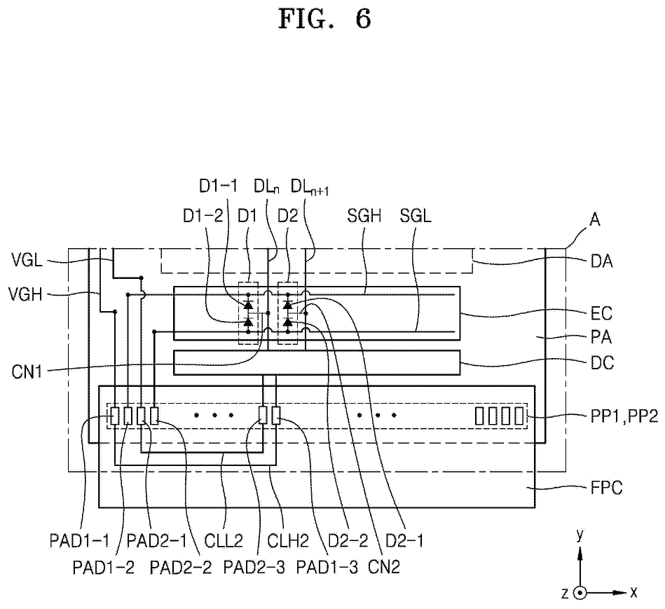

For reference, in the description of FIGS. 4 to 6, contents identical to or repeating those described with reference to FIGS. 1 to 3 may be omitted. In addition, FIGS. 4 and 5 show the display apparatus in a state of a manufacturing process before a printed circuit board is attached, and FIG. 6 shows the display apparatus in a state after the printed circuit board is attached.

As shown in FIG. 4, the display apparatus according to an embodiment may include a first gate line VGH having a first gate voltage, and a second gate line VGL having a second gate voltage.

The first gate line VGH and the second gate line VGL may be configured to receive a voltage of a preset size from the scan driver SC1. As an example, the first gate line VGH may have the first gate voltage, and the first gate voltage may be a high-level voltage. As an example, the second gate line VGL may have the second gate voltage, and the second gate voltage may be a low-level voltage.

As shown in FIG. 4, the display apparatus according to an embodiment may include a first data line DLn configured to transfer a first data signal to a first pixel line, and a second data line DLn+1 configured to transfer a second data signal to a second pixel line.

As an example, the first pixel line and the second pixel line may denote pixels arranged in a ±y axis direction. A line configured to transfer a first data signal to the first pixel line may be referred to as the first data line DLn, and the first data line DLn may extend in an approximate ±y axis direction. A line configured to transfer a second data signal to the second pixel line may be referred to as the second data line DLn+1, and the second data line DLn+1 may extend in the approximate ±y axis direction.

Although, for convenience of description, the embodiment is described based on two pixel lines, it is obvious that more pixel lines may be arranged actually, and more data lines corresponding thereto may be arranged.

A first data signal and a second data signal may be signals generated by the data driver DC. To transfer a first data signal and a second data signal, the first data line DLn and the second data line DLn+1 may electrically connect each pixel line to the data driver DC.

The electrostatic blocking portion EC may include a first electrostatic line SGH and a second electrostatic line SGL. As an example, the first electrostatic line SGH may be electrically connected to the first data line DLn by a first diode structure D1, and electrically connected to the second data line DLn+1 by a second diode structure D2. As an example, the second electrostatic line SGL may be connected to the first data line DLn by the first diode structure D1, and electrically connected to the second data line DLn+1 by the second diode structure D2.

The first diode structure D1 and the second diode structure D2 may define directions such that charges flow in a desired direction. The first diode structure D1 and the second diode structure D2 may be constructions configured to prevent charges occurring due to static electricity from entering an inner structure of the panel.

The first diode structure D1 may include a first-first diode D1-1, a first-second diode D1-2, and a first connection CN1. The first connection CN1 may include a first end connected between the first-first diode D1-1 and the first-second diode D1-2, and a second end connected to the first data line DLn. The second diode structure D2 may include a second-first diode D2-1, a second-second diode D2-2, and a second connection CN2. The second connection CN2 may include a first end connected between the second-first diode D2-1 and the second-second diode D2-2, and a second end connected to the second data line DLn+1.

As shown in FIG. 4, the first electrostatic line SGH may be electrically separated from the first gate line VGH, and the second electrostatic line SGL may be electrically separated from the second gate line VGL. As a result, the electrostatic blocking portion EC may be electrically connected to or separated from the first gate line VGH and the second gate line VGL depending on the case.

As an example, the electrostatic blocking portion EC may be arranged between the display area DA and the data driver DC. Because the electrostatic blocking portion EC is arranged between the display area DA and the data driver DC, static electricity or charges generated during the manufacturing process may be effectively prevented from being applied to the pixel PX or the pixel circuit PC arranged in the display area DA.

The first pad portion PP1 may include a 1-1 pad PAD1-1, a 1-2 pad PAD1-2, and a 1-3 pad PAD1-3. In addition, the first pad portion PP1 may include a 2-1 pad PAD2-1, a 2-2 pad PAD2-2, and a 2-3 pad PAD2-3. Although the first pad portion PP1 may include more pads, only some pads are shown, for convenience of description.

The 1-1 pad PAD1-1 may be electrically connected to the first gate line VGH. The 1-2 pad PAD1-2 may be electrically connected to the first electrostatic line SGH. The 1-1 pad PAD1-1 and the 1-2 pad PAD1-2 may be apart from each other and arranged to be apart from each other by an interval designed in advance. Although it is shown that the 1-1 pad PAD1-1 and the 1-2 pad PAD1-2 are arranged to be adjacent side by side, for convenience of description, this is just an example and the scope of the disclosure is not limited thereto. The arrangement of the pads may change depending on change in design. However, the 1-1 pad PAD1-1 and the 1-2 pad PAD1-2 may be electrically separated from each other.

The 1-2 pad PAD1-2 may be electrically connected to the second gate line VGL. The 2-2 pad PAD2-2 may be electrically connected to the second electrostatic line SGL. The 2-1 pad PAD2-1 and the 2-2 pad PAD2-2 may be apart from each other and arranged to be apart from each other by an interval designed in advance. Although it is shown that the 2-1 pad PAD2-1 and the 2-2 pad PAD2-2 are arranged to be adjacent side by side, for convenience of description, this is just an example and the scope of the disclosure is not limited thereto. The arrangement of the pads may change depending on change in design. However, the 2-1 pad PAD2-1 and the 2-2 pad PAD2-2 may be electrically separated from each other.

The 1-3 pad PAD1-3 and the 2-3 pad PAD2-3 may be electrically connected to the data driver DC. The 1-3 pad PAD1-3 and the 2-3 pad PAD2-3 may be apart from each other and arranged to be apart from each other by an interval designed in advance. Although it is shown that the 1-3 pad PAD1-3 and the 2-3 pad PAD2-3 are arranged to be adjacent side by side, for convenience of description, this is just an example and the scope of the disclosure is not limited thereto. The arrangement of the pads may change depending on change in design. However, the 1-3 pad PAD1-3 and the 2-3 pad PAD2-3 may be electrically separated from each other.

As shown in FIG. 5, to protect the internal structure of the panel from static electricity generated during the manufacturing process, it is required to apply the first gate voltage and the second gate voltage to the electrostatic blocking portion EC. Accordingly, to electrically connect the first gate line VGH to the first electrostatic line SGH, a first additional connection portion CLH1 electrically connecting the 1-1 pad PAD1-1 to the 1-2 pad PAD1-2 may be provided.

The first additional connection portion CHL1 may electrically connect the 1-1 pad PAD1-1 to the 1-2 pad PAD1-2. In addition, to electrically connect the second gate line VGL to the second electrostatic line SGL, a second additional connection portion CLL1 electrically connecting the 2-1 pad PAD2-1 to the 2-2 pad PAD2-2 may be provided. The second additional connection portion CLL1 may electrically connect the 2-1 pad PAD2-1 to the 2-2 pad PAD2-2. The first additional connection portion CLH1 may be a wiring type including a conductive material or a pad type including a conductive material.

As shown in FIG. 6, after the printed circuit board FPC is attached, charges caused by electrostatic discharge may be absorbed by the printed circuit board FPC. Accordingly, after the printed circuit board FPC is attached, the 1-1 pad PAD1-1 and the 1-2 pad PAD1-2 do not need to be electrically connected to each other, and the 2-1 pad PAD2-1 and the 2-2 pad PAD2-2 do not need to be electrically connected to each other. Accordingly, in the process of attaching the printed circuit board FPC, the first additional connection portion CLH1 and the second additional connection portion CLL1 may be omitted or removed. The second additional connection portion CLL1 may be a wiring type including a conductive material or a pad type including a conductive material.

As shown in FIG. 6, a first connection member CLH2 included in the printed circuit board FPC may electrically connect the 1-1 pad PAD1-1 to the 1-3 pad PAD1-3. Accordingly, the first gate line VGH may be electrically connected to the data driver DC. The second connection member CLL2 included in the printed circuit board FPC may electrically connect the 2-1 pad PAD2-1 to the 2-3 pad PAD2-3. Accordingly, the second gate line VGL may be electrically connected to the data driver DC.

As an example, the printed circuit board FPC may include the first connection member CLH2 and the second connection member CLL2. The printed circuit board FPC may include the second pad portion PP2, and the second pad portion PP2 may include separate pads corresponding to the 1-1 pad PAD1-1, the 1-2 pad PAD1-2, and the 1-3 pad PAD1-3. In addition, the second pad portion PP2 may include separate other pads corresponding to the 2-1 pad PAD2-1, the 2-2 pad PAD2-2, and the 2-3 pad PAD2-3. In addition, the printed circuit board FPC may be attached in the peripheral area PA of the substrate. As an example, the printed circuit board FPC may be attached to the 1-1 pad PAD1-1, the 1-2 pad PAD1-2, the 1-3 pad PAD1-3, the 2-1 pad PAD2-1, the 2-2 pad PAD2-2, and the 2-3 pad PAD2-3.

The first connection member CLH2 and the second connection member CLL2 may be wiring types including a conductive material or pad types including a conductive material.

As shown in FIGS. 4 to 6, a method (referred to as a manufacturing method, hereinafter) of manufacturing the display apparatus according to an embodiment may include forming, on the substrate, the first gate line VGH having the first gate voltage, and the second gate line VGL having the second gate voltage. As an example, the first gate voltage may be a gate high-level voltage, and the second gate voltage may be a gate low-level voltage.

The manufacturing method according to an embodiment may further include forming the first data line DLn configured to transfer a first data signal to the first pixel line, and the second data line DLn+1 configured to transfer a second data signal to the second pixel line. As an example, a first data signal and a second data signal may be generated by the data driver DC.

The manufacturing method according to an embodiment may include forming, on the substrate, the electrostatic blocking portion EC including the first electrostatic line SGH electrically connected to the first gate line VGH, and the second electrostatic line SGL electrically connected to the second gate line VGL. In addition, the electrostatic blocking portion EC may further include the first diode structure D1 and the second diode structure D2.

As an example, the first electrostatic line SGH may be electrically connected to the first data line DLn by the first diode structure D1, and electrically connected to the second data line DLn+1 by the second diode structure D2. As an example, the second electrostatic line SGL may be electrically connected to the first data line DLn by the first diode structure D1, and electrically connected to the second data line DLn+1 by the second diode structure D2.

As an example, the first data line DLn and the second data line DLn+1 may each cross the first electrostatic line SGH and the second electrostatic line SGL in a plan view. As an example, the first data line DLn and the second data line DLn+1 may each cross the first electrostatic line SGH and the second electrostatic line SGL in an approximately perpendicular direction in a plan view.

The manufacturing method according to an embodiment may further include forming, on the substrate, the data driver DC configured to generate a first data signal and a second data signal. The forming of the data driver DC may be performed prior to the forming of the data line, or may be performed after the forming of the data line.

The manufacturing method according to an embodiment may further include electrically separating the first gate line VGH from the first electrostatic line SGH and electrically separating the second gate line VGL from the second electrostatic line SGL. The electrically separating may be performed after the forming of the electrostatic blocking portion EC including the first electrostatic line SGH electrically connected to the first gate line VGH.

As shown in FIGS. 4 to 6, to separate the first gate line VGH from the first electrostatic line SGH, the first additional connection portion CLH1 may be removed or disconnected, and to separate the second gate line VGL from the second electrostatic line SGL, the second additional connection portion CLL1 may be removed or disconnected.

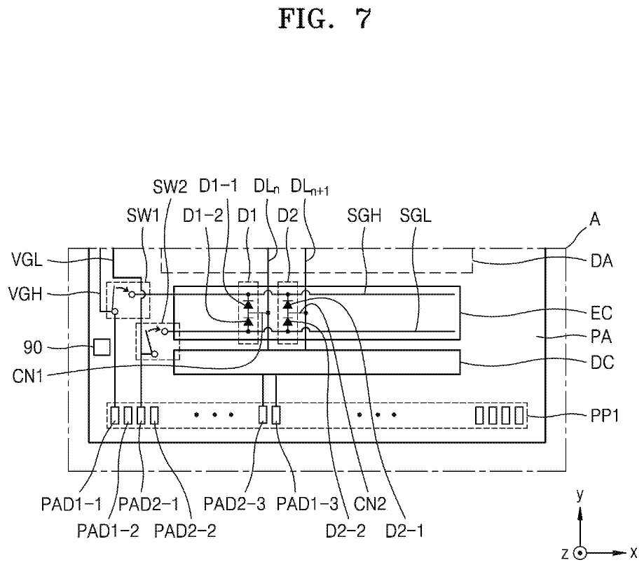

Alternatively, as shown in FIGS. 7 to 9, to separate the first gate line VGH from the first electrostatic line SGH, a first switch SW1 (see FIG. 7 and the like) may be used, and to separate the second gate line VGL from the second electrostatic line SGL, a second switch SW2 (see FIG. 7 and the like) may be used. A switch controller 90 (see FIG. 7) described below may be configured to control the first switch SW1 to electrically separate or disconnect the first gate line VGH and the first electrostatic line SGH. In addition, the switch controller 90 described below may be configured to control the second switch SW2 to electrically separate or disconnect the second gate line VGL and the second electrostatic line SGL.

The manufacturing method according to an embodiment may further include attaching the printed circuit board FPC to the substrate, wherein the printed circuit board FPC includes the first connection member CLH2 electrically connects the first gate line VGH to the data driver DC, and the second connection member CLL2 electrically connects the second gate line VGL to the data driver DC. That is, electrical connection between the first gate line VGH and the first electrostatic line SGH may be released, and the first gate line VGH may be electrically connected to the data driver DC. In addition, electrical connection between the second gate line VGL and the second electrostatic line SGL may be released, and the second gate line VGL may be electrically connected to the data driver DC. After the printed circuit board FPC is attached, an electrostatic discharge prevention circuit or an electrostatic discharge structure built in the printed circuit board FPC itself may be used.

The manufacturing method according to an embodiment may further include forming the 1-1 pad PAD1-1 electrically connected to the first gate line VGH, the 2-1 pad PAD2-1 electrically connected to the second gate line VGL, and forming the 1-2 pad PAD1-2 electrically connected to the first electrostatic line SGH and the 2-2 pad PAD2-2 electrically connected to the second electrostatic line SGL.

As an example, the 1-1 pad PAD1-1 and the 1-2 pad PAD1-2 may be electrically separated from each other, and the 1-1 pad PAD1-1 and the 1-2 pad PAD1-2 may be electrically connected to each other by the first additional connection portion CLH1, or the electrical connection may be released afterwards. The 2-1 pad PAD2-1 and the 2-2 pad PAD2-2 may be electrically separated from each other, and the 2-1 pad PAD2-1 and the 2-2 pad PAD2-2 may be electrically connected to each other by the second additional connection portion CLL1, or the electrical connection may be released afterwards.

As an example, the forming of the electrostatic blocking portion EC may include forming the first additional connection portion CLH1 electrically connecting the 1-1 pad PAD1-1 to the 1-2 pad PAD1-2, and forming the second additional connection portion CLL1 electrically connecting the 2-1 pad PAD2-1 to the 2-2 pad PAD2-2. Then, the electrically separating of the first gate line VGH from the first electrostatic line SGH, and the electrically separating of the second gate line VGL from the second electrostatic line SGL may include removing or disconnecting the first additional connection portion CLH1, and removing or disconnecting the second additional connection portion CLL1.

The manufacturing method according to an embodiment may further include forming the 1-3 pad PAD1-3 and the 2-3 pad PAD2-3 electrically connected to the data driver DC. As an example, the first connection member CLH2 included in the printed circuit board FPC may electrically connect the 1-1 pad PAD1-1 to the 1-3 pad PAD1-3. As an example, the second connection member CLL2 included in the printed circuit board FPC may electrically connect the 2-1 pad PAD2-1 to the 2-3 pad PAD2-3.

FIGS. 7 to 9 are schematic plan views of an example of a region A of FIG. 1 according to time series.

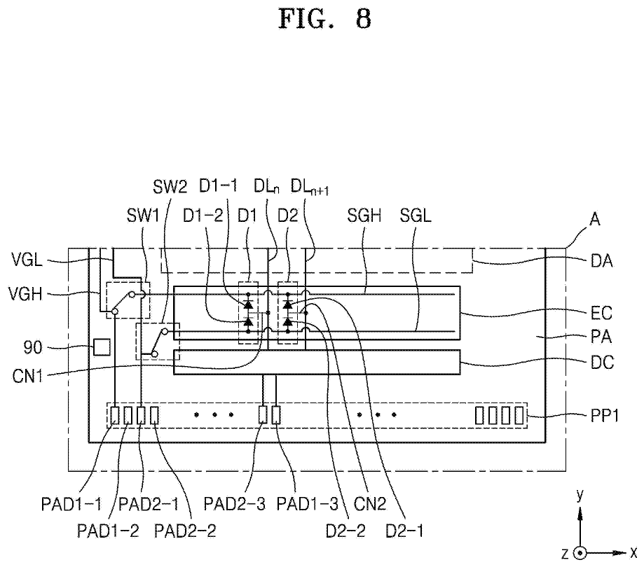

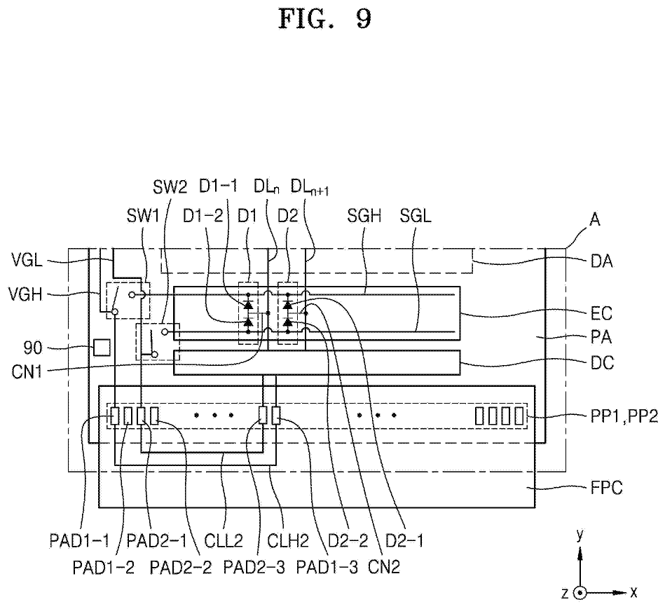

For reference, in the description of FIGS. 7 to 9, contents identical to or repeating those described with reference to FIGS. 1 to 6 may be omitted. In addition, FIGS. 7 and 8 show the display apparatus in a state of the manufacturing process before the printed circuit board is attached, and FIG. 9 shows the display apparatus in a state after the printed circuit board is attached.

As shown in FIG. 7, the display apparatus according to an embodiment may include the first switch SW1 electrically connecting or electrically separating the first gate line VGH and the first electrostatic line SGH. In addition, the display apparatus according to an embodiment may further include the second switch SW2 electrically connecting or electrically separating the second gate line VGL and the second electrostatic line SGL. In addition, the display apparatus according to an embodiment may further include the switch controller 90 configured to control the first switch SW1 and the second switch SW2.

The switch controller 90 may control on/off of the first switch SW1 and the second switch SW2. As an example, when the first switch SW1 is in an on-state, the first gate line VGH and the first electrostatic line SGH may be electrically connected to each other. As an example, when the first switch SW1 is in an off-state, the first gate line VGH and the first electrostatic line SGH may be electrically separated or disconnected. The driving of the first switch SW1 may be performed according to a control command received from the switch controller 90.

As an example, when the second switch SW2 is in an on-state, the second gate line VGL and the second electrostatic line SGL may be electrically connected to each other. As an example, when the second switch SW2 is in an off-state, the second gate line VGL and the second electrostatic line SGL may be electrically separated or disconnected. The driving of the second switch SW2 may be performed according to a control command received from the switch controller 90.

As an example, the first gate line VGH may have the first gate voltage, and the first gate voltage may be a high-level voltage. The second gate line VGL may have the second gate voltage, and the second gate voltage may be a low-level voltage.

The switch controller 90 may be configured to control the first switch SW1 and the second switch SW2, based on the electrical connection states between the first gate line VGH and the second gate line VGL, and the data driver DC.

As an example, a first state may be defined as a state of the display apparatus before including the printed circuit board FPC (or attaching the printed circuit board FPC to the substrate). In the first state, the switch controller 90 may be configured to control the first switch SW1 to electrically connect the first gate line VGH to the first electrostatic line SGH, and configured to control the second switch SW2 to electrically connect the second gate line VGL to the second electrostatic line SGL.

As an example, a second state may be defined as a state of the display apparatus after including the printed circuit board FPC. In the second state or just before entering the second state, the switch controller 90 may be configured to control the first switch SW1 to electrically separate the first gate line VGH from the first electrostatic line SGH, and configured to control the second switch SW2 to electrically separate the second gate line VGL from the second electrostatic line SGL.

The switch controller 90 configured to generate control commands of FIGS. 7 to 9 may be configured to automatically control the first switch SW1 and the second switch SW2. Alternatively, the switch controller 90 configured to generate control commands of FIGS. 7 to 9 may be configured to control the first switch SW1 and the second switch SW2, based on user commands input by a user.

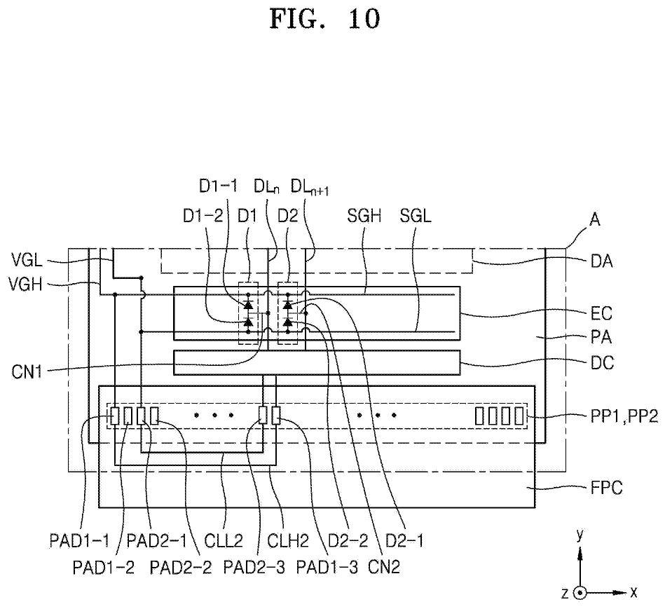

FIG. 10 is a schematic plan view of a portion of a display apparatus according to a comparative example.

In the description of FIG. 10, contents identical to or repeating those described with reference to FIGS. 1 to 9 may be omitted, and the plan view shown in FIG. 10 may be a view mainly showing a region corresponding to the region A of FIG. 1.

As shown in FIG. 10, the display apparatus according to a comparative example may include the electrostatic blocking portion EC, and the electrostatic blocking portion EC may include the first electrostatic line SGH and the second electrostatic line SGL. However, in the display apparatus according to the comparative example, the first electrostatic line SGH is not electrically separated from the first gate line VGH, and the second electrostatic line SGL is not electrically separated from the second gate line VGL.

In other words, the first electrostatic line SGH always has the first gate voltage of the first gate line VGH, and the second electrostatic line SGL also always has the second gate voltage of the second gate line VGL. As described above, the first gate voltage may be a gate high-level voltage, and the second gate voltage may be a gate low-level voltage. In this case, the first data line DLn and the second data line DLn+1 may be connected to both the first electrostatic line SGH and the second electrostatic line SGL. Accordingly, the first data line DLn and the second data line DLn+1 may be directly or indirectly affected by the gate high-level voltage and the gate low-level voltage.

As a result, due to a difference in voltage magnitude between the gate high-level voltage and the gate low-level voltage, corrosion may occur between the first data line DLn and the second data line DLn+1. Accordingly, it is required that the first electrostatic line SGH is physically or electrically separated from the first gate line VGH, and the first electrostatic line SGH is selectively connected to the first gate line VGH according to the manufacturing process of the display apparatus.

Particularly, the printed circuit board FPC itself may include the ESD protection circuit or the ESD protection structure. An ESD protection performance of the ESD protection circuit or the ESD protection structure included in the printed circuit board FPC itself may be more excellent than the electrostatic blocking portion EC. Accordingly, in the case where the printed circuit board FPC is attached or mounted on the substrate, to prevent the danger of corrosion between the data lines, it is required to block a gate high-level voltage and a gate low-level voltage applied to the first electrostatic line SGH and the second electrostatic line SGL.

To block a gate high-level voltage and a gate low-level voltage applied to the first electrostatic line SGH and the second electrostatic line SGL, the embodiments of FIGS. 4 to 6 include technical spirit of selectively separating or connecting the first electrostatic line SGH and the first gate line VGH, and includes a technical spirit of selectively separating or connecting the second electrostatic line SGL and the second gate line VGL according to the manufacturing process of the display apparatus. Likewise, the embodiments of FIGS. 7 to 9 include the same spirit as the embodiments of FIGS. 4 to 6 and have a difference in that the switch is used instead of the connection member as a means for performing the same spirit.

As a result, the display apparatus according to an embodiment may prevent corrosion between the first data line and the second data line (or a plurality of data lines) and have higher reliability compared to the display apparatus according to the comparative example.

According to the embodiment, the display apparatus in which damage to a circuit caused by ESD may be prevented, and the manufacturing method thereof may be implemented. However, the scope of the disclosure is not limited by this effect.

Embodiments described herein should be considered in a descriptive sense and not for purposes of limitation. Descriptions of features or aspects within each embodiment should typically be considered as available for other similar features or aspects in other embodiments. While embodiments have been described with reference to the figures, it will be understood by those of ordinary skill in the art that various changes in form and details may be made therein without departing from the spirit and scope as defined by the following claims.

What is claimed is:

1. A display apparatus comprising:
a first gate line configured to receive a first gate voltage;
a second gate line configured to receive a second gate voltage;
a first data line configured to transfer a first data signal to a first pixel line;
a second data line configured to transfer a second data signal to a second pixel line; and
an electrostatic blocking portion including a first electrostatic line and a second electrostatic line,
wherein the first electrostatic line is connected to the first data line by a first diode structure and connected to the second data line by a second diode structure,
the second electrostatic line is connected to the first data line by the first diode structure and is connected to the second data line by the second diode structure, and
the first electrostatic line is electrically separated from the first gate line, and the second electrostatic line is electrically separated from the second gate line.

2. The display apparatus of claim 1, wherein the first gate voltage is a gate high-level voltage, and the second gate voltage is a gate low-level voltage.

3. The display apparatus of claim 2, wherein the first gate line is connected to a 1-1 pad, the first electrostatic line is connected to a 1-2 pad, and the 1-2 pad is apart from the 1-1 pad.

4. The display apparatus of claim 3, wherein the 1-1 pad and the 1-2 pad are electrically separated from each other.

5. The display apparatus of claim 4, wherein the second gate line is connected to a 2-1 pad, the second electrostatic line is connected to a 2-2 pad, and the 2-2 pad is apart from the 2-1 pad.

6. The display apparatus of claim 5, wherein the 2-1 pad and the 2-2 pad are electrically separated from each other.

7. The display apparatus of claim 4, further comprising a data driver configured to generate the first data signal and the second data signal.

8. The display apparatus of claim 7, further comprising:
a 1-3 pad electrically connected to the data driver; and
a first connection member connecting the 1-1 pad to the 1-3 pad.

9. The display apparatus of claim 8, further comprising:
a 2-3 pad electrically connected to the data driver; and
a second connection member connecting the 2-1 pad to the 2-3 pad.

10. The display apparatus of claim 9, further comprising a printed circuit board including the first connection member and the second connection member,
wherein the printed circuit board is attached to the 1-1 pad, the 1-2 pad, the 1-3 pad, the 2-1 pad, the 2-2 pad, and the 2-3 pad.

11. The display apparatus of claim 7, wherein the electrostatic blocking portion is arranged between a display area in which at least one pixel is arranged, and the data driver in a plan view.

12. A method of manufacturing a display apparatus, the method comprising:
forming, on a substrate, a first gate line configured to receive a first gate voltage and a second gate line configured to receive a second gate voltage;
forming, on the substrate, a first data line configured to transfer a first data signal to a first pixel line, and a second data line configured to transfer a second data signal to a second pixel line;
forming, on the substrate, an electrostatic blocking portion including a first electrostatic line electrically connected to the first gate line, and a second electrostatic line electrically connected to the second gate line;
forming, on the substrate, a data driver configured to generate the first data signal and the second data signal;
electrically separating the first gate line from the first electrostatic line and electrically separating the second gate line from the second electrostatic line; and
attaching a printed circuit board to the substrate,
wherein the printed circuit board includes a first connection member electrically connecting the first gate line to the data driver, and a second connection member electrically connecting the second gate line to the data driver.

13. The method of claim 12, wherein the first gate voltage is a gate high-level voltage, and the second gate voltage is a gate low-level voltage.

14. The method of claim 13, further comprising:
forming a 1-1 pad electrically connected to the first gate line and a 2-1 pad electrically connected to the second gate line; and
forming a 1-2 pad electrically connected to the first electrostatic line and forming a 2-2 pad electrically connected to the second electrostatic line.

15. The method of claim 14, wherein the forming of the electrostatic blocking portion includes forming a first additional connection portion electrically connecting the 1-1 pad to the 1-2 pad, and forming a second additional connection portion electrically connecting the 2-1 pad to the 2-2 pad.

16. The method of claim 15, wherein the electrically separating of the first gate line from the first electrostatic line and the electrically separating of the second gate line from the second electrostatic line include removing or disconnecting the first additional connection portion, and removing or disconnecting the second additional connection portion.

17. The method of claim 16, further comprising forming a 1-3 pad and a 2-3 pad, which are electrically connected to the data driver,
wherein the first connection member electrically connects the 1-1 pad to the 1-3 pad, and the second connection member electrically connects the 2-1 pad to the 2-3 pad.

18. A display apparatus comprising:
a first gate line configured to receive a first gate voltage;
a second gate line configured to receive a second gate voltage;
a first data line configured to transfer a first data signal to a first pixel line;
a second data line configured to transfer a second data signal to a second pixel line;
an electrostatic blocking portion including a first electrostatic line and a second electrostatic line, the first electrostatic line is connected to the first data line by a first diode structure and connected to the second data line by a second diode structure, and the second electrostatic line is connected to the first data line by the first diode structure and connected to the second data line by the second diode structure;
a first switch configured to electrically connect the first gate line and the first electrostatic line or electrically separate the first gate line and the first electrostatic line;
a second switch configured to electrically connect the second gate line and the second electrostatic line or electrically separate the second gate line and the second electrostatic line; and
a switch controller configured to control the first switch and the second switch.

19. The display apparatus of claim 18, wherein the first gate voltage is a gate high-level voltage, and the second gate voltage is a gate low-level voltage.

20. The display apparatus of claim 19, further comprising:
a data driver configured to generate the first data signal and the second data signal; and
a printed circuit board including a first connection member electrically connecting the first gate line to the data driver, and a second connection member electrically connecting the second gate line to the data driver.

21. The display apparatus of claim 20, wherein the switch controller is configured to control the first switch and the second switch, based on an electrical connection state of the first gate line, the second gate line, and the data driver.

22. The display apparatus of claim 20, wherein, when a first state is a state of the display apparatus before including the printed circuit board, in the first state, the switch controller is configured to control the first switch to electrically connect the first gate line to the first electrostatic line, and configured to control the second switch to electrically connect the second gate line to the second electrostatic line.

23. The display apparatus of claim 20, wherein, when a second state is a state of the display apparatus after including the printed circuit board, in the second state, the switch controller is configured to control the first switch to electrically separate the first gate line from the first electrostatic line, and configured to control the second switch to electrically separate the second gate line from the second electrostatic line.
